(19) United States
(12) Patent Application Publication
(10) Pub. No.: US 2012/0228441 A1
(43) Pub. Date: Sep. 13, 2012

(54) FLEXIBLE AND RETRACTABLE SUPPORT ARM FOR ELECTRONIC DEVICES

(76) Inventor: Rodrigo Ceron, Vernon (CA)

(21) Appl. No.: 13/045,530

(22) Filed: Mar. 11, 2011

(51) Int. Cl. H05K 7/00

(52) U.S. Cl. 248/125.7

(57) ABSTRACT

The Flexible and retractable support arm for electronic devices with optional electrical connection is an apparatus to be used in a very comfortable position allowing the user to interact with the device attached to it, to position it in a way that fits perfectly his or her viewing needs, extending the arm to the desired length, rotate the mini flexible arm to adjust the angle or rotate the cradle to set the perfect position to interact with the electronic device installed. Additionally because it is optionally equipped with electrical connection, the user is able to charge the electronic device while in use. When not in use this flexible arm can be retracted inside the tubular hollow base.

### BACKGROUND OF THE INVENTION

### Field of the Invention

The present invention relates generally to holders of portable electronic devices.

Electronic devices delivering media, data and in general entertainment are very popular in today's market allowing the users to enjoy such information throughout the day because of their portability. There are a variety of different holders and support stands created to place these devices to either electrically charge the media player, or to provide a base to watch and listen video files. Some of these stands and holders have some capacity to adjust the position to provide an easy hands free video viewing and usage. When trying to use these existing apparatus to interact with portable electronic devices while in bed or similar comfortable position, those are, too small, too bulky, unstable, and no provide electrical connection for the charger.

### Related Patents

1.—7,614,909 B2 Tek-Chain Co
2.—20090060473 A1 Hans and Marion Kohte
3.—20080158411 A1 Jamey GFinberg
4.—20080087789 A1 Debra Haynes
5.—20090189039 A1 Darrin LaBuda

### BRIEF SUMMARY OF THE INVENTION

The main object of this invention is to provide an aesthetic, ergonomic, intuitive, solid and retractable support for electronic devices (Ipod, Ipad, Kindle or similar), to transform this multimedia platforms in a personal source of knowledge, entertainment and communication when in bed or any other comfortable position.

Other object of the invention is to transform the use of this multimedia devices (Ipod, Ipad, Kindle or similar) in a real and environmentally friendly alternative to the use of TV sets in environments such as bedrooms, hospital rooms, offices, devices that use a large amount of energy and are a source of sound and light contamination for whose are not watching them.

### BRIEF DESCRIPTION OF THE DRAWINGS

The drawings illustrate this invention and its use, however it is to be understood that it is not the intention to limit the use of this invention.

FIG. 1 is the apparatus showing the flexible arm extended out of the tubular base and equipped with retractable electrical connection.

FIG. 2 is a longitudinal section of the tubular base to show the way the tubular base works as an sleeve for the retractable and flexible arm, the retractable electric connection and the sliding lever-foot base adjustable anchoring group.

FIG. 3 is a view of the apparatus with the flexible arm retracted and no equipped with retractable electric connection.

FIG. 4 is a larger scale hybrid top view-section of the rotating cradle—magnet and plate—mini flexible arm, holder group, showing the optional electric connection.

FIG. 5 is a larger scale hybrid side view-section of the rotating cradle—magnet and plate—mini flexible arm, holder group, showing the optional electric connection.

FIG. 6 is a larger scale back view of the rotating cradle—magnet and plate—mini flexible arm, holder group, showing the optional electric connection.

FIG. 7 is a larger scale front view of the rotating cradle—magnet and plate—mini flexible arm, holder group, showing the optional electric connection.

FIG. 8 is a larger scale view from the bottom of the rotating cradle—magnet and plate—mini flexible arm, holder group, showing the optional electric connection.

FIG. 9 Illustrate a person using the invention.

### DETAILED DESCRIPTION OF THE INVENTION

The description that follows is presented to enable one skilled in the art to make and use the present invention, and is provided in the context of a particular application and its requirements.

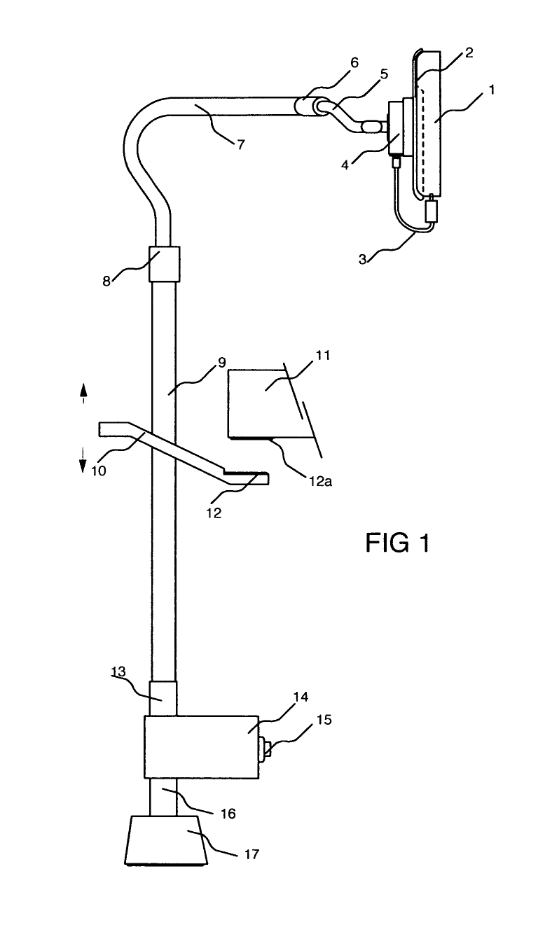

FIG. 1 is a representative lateral view of the device. As shown in FIG. 1 the invention consists essentially of a tubular hollow base 9 to be anchored to a bed, desk or other piece of furniture or fix element 11 using the adjustable spring equipped group foot base 17-sliding lever 10. To anchor the apparatus, just place the foot base 17 in the desired place between the floor and the bed, desk or any horizontal flat surface 11, push the tubular base 9 to compress the spring inside the element 17, makes the tubular base vertical and lift the lever 10 to make the surfaces 12 and 12a be in tight contact, then, release the pressure on the tubular base. The bottom of the tubular base is connected to the electrical connection box 14 that holds the retractable electric wire mechanism 22 and the external connection 15 to an external source of power or data. The top end of the tubular base is ended with a non threaded sleeve 8 allowing the flexible arm 7 to go through smoothly in a way that this flexible arm can move to reach any desired length or angle. The Flexible arm 7 ends at the top with a fitting 6 that connect to the mini flexible arm 5 attached to the cradle with a rotating connector. The cradle base 4 has two versions, one with electrical plug to connect the charger extension and the other without.

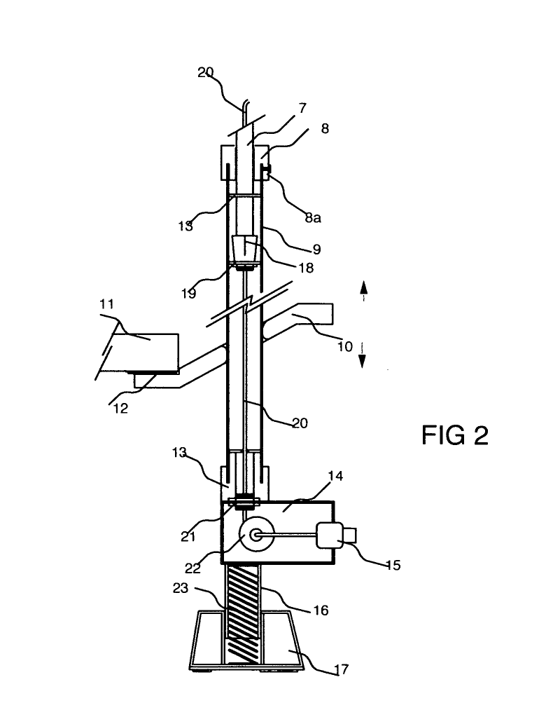

FIG. 2 is the graphic representation of a section of the tubular hollow base to show both ends of the base 9 with the top 8 and bottom 13 end sleeves attached. As showing the graphic, the top sleeve is provided with a screw 8a to hold this end in place. The bottom of the hollow base 9 ends with a threaded sleeve who connect the base with the group casing 14-retractable electric wire 20, wheel 22 and connector 15.

FIG. 3 Is the representation of the device as described in FIG. A, showing the flexible and retractable arm 7 retracted and without electrical connection elements, 3-14-15-20-22.

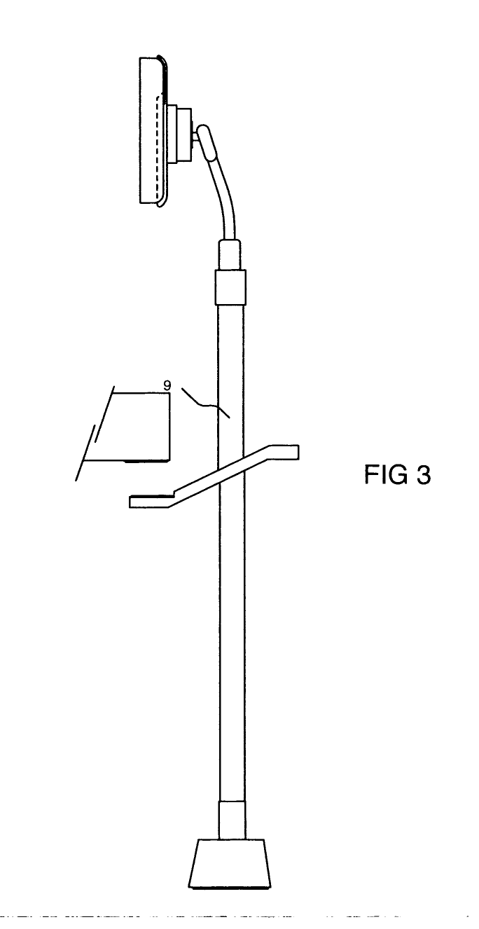

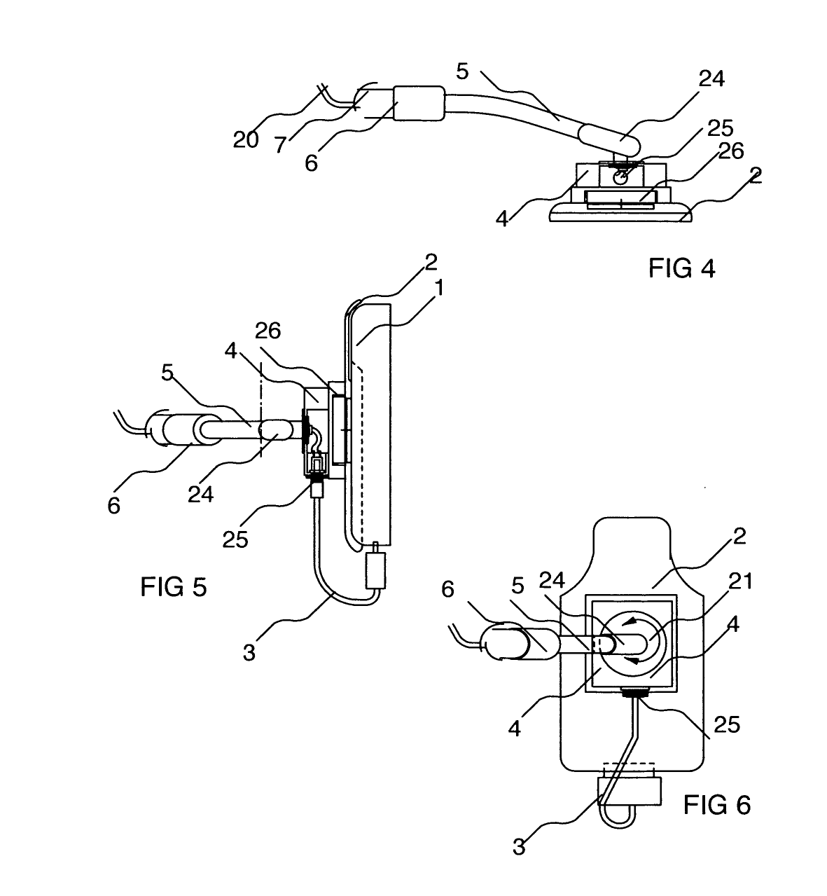

FIG. 4 is a larger scale hybrid top view-section of the rotating cradle 2—magnet and plate 26—mini flexible arm 5, holder group, showing the optional electric connection 25. It shows how the flexible mini arm is connected to the main arm with the fitting 6. The mini flexible arm in 5 ends in a rigid connector 24 connected to the base 4 of the supporting cradle with a pressure washer that allows the group to rotate.

FIG. 5 Illustrates a side view-section of the joint between the mini flexible arm and the connection with the cradle 2 and shows how the hollow rigid connector 24 attached to the base 4 with a pressure washer, allows the optional electrical wire to connect the terminals in 25 that provides electrical power to the extension 3 and the device 1 This graphic also shows the optional electric wire 20 coming from the flexible arm ending with a connector 25 allowing to connect an extension charger cable 3 to the electronic device 1.

FIG. 6 shows a view from the back of the mini flexible arm 5 attached to the main arm with the fitting 6, connected to the rotating cradle base 4 with the rigid connector 24, with a pressure washer that allows the group to rotate.

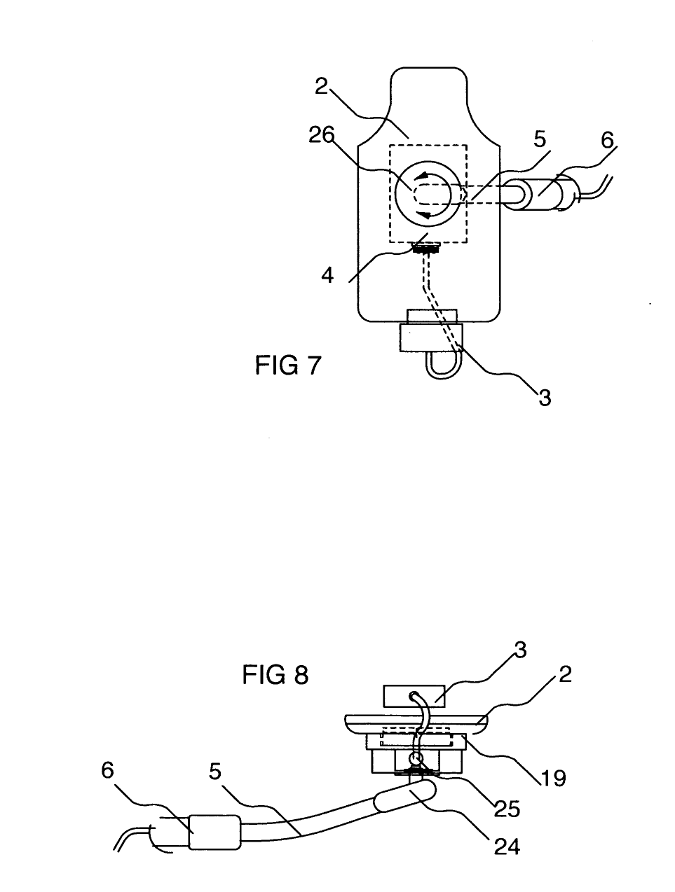

FIG. 7 is a frontal view of the rotating cradle 2, showing the circular perforation that allows the magnet in 26 makes contact with the metallic plate previously attached to the electronic device.

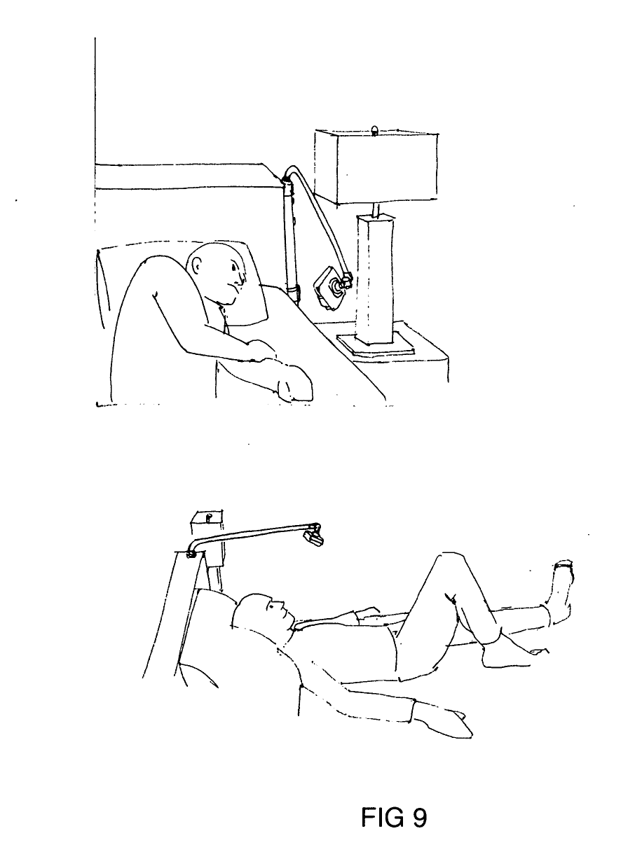

FIG. 8 is a bottom view of the group showing the rotating cradle 2—magnet and plate 26—mini flexible arm 5, holder group, showing the optional electric connection 25. It shows how the flexible mini arm is connected to the main arm with the fitting 6. The mini flexible arm in 5 ends in a rigid connector 24 connected to the base 4 of the supporting cradle with a pressure washer that allows the group to rotate.

FIG. 9 Illustrates how a person can enjoy the use of this apparatus while in bed in any comfortable position. This illustration is not intended to limit the use and possibilities of the apparatus.

The proportions of the different elements in the drawings can vary to accommodate the different sizes electronic devices to attach to the apparatus.

What is claimed in this application is:

1. A flexible retractable support comprising:

2. A tubular hollow base-sleeve to hold the main flexible arm.

3. A main flexible arm that, when extended capable of being bent, rotated from the base, or be retracted inside the tubular base;

4. A secondary mini flexible arm attached to the main arm to allow the user 8 more flexible and precise adjustments.

5. A rotating cradle equipped with a magnet to hold an electronic device previously equipped with a metallic plate.

6. A spring equipped Foot base-sliding lever group to install the apparatus in a easy way.

7. A box attached at the bottom of the tubular base and casing the wheel to retract the electric connection to be attached to the electronic device in the cradle on one end, and a charger or electronic component at the other end.
